(19) United States
(12) Patent Application Publication
(10) Pub. No.: US 2015/0213867 A1
(43) Pub. Date: Jul. 30, 2015

(54) MULTI-LEVEL CELL DESIGNS FOR HIGH DENSITY LOW POWER GSHE-STT MRAM

(71) Applicant: QUALCOMM Incorporated, San Diego, CA (US)

(72) Inventors: Wenqing WU, San Diego, CA (US); Kendrick Hoy Leong YUEN, San Diego, CA (US); Karim ARABI, San Diego, CA (US)

(21) Appl. No.: 14/479,539

(22) Filed: Sep. 8, 2014

Related U.S. Application Data
(60) Provisional application No. 61/932,768, filed on Jan. 28, 2014.

(51) Int. Cl. G11C 11/16; H01L 43/14; G11C 11/18; G11C 11/56

(52) U.S. Cl. CPC G11C 11/1675; G11C 11/1673; G11C 11/5607; H01L 43/14; G11C 11/18; G11C 11/1659

(57) ABSTRACT

Systems and methods are directed to multi-level cell (MLC) comprising: two or more programmable elements coupled to a common access transistor, wherein each one of the two or more programmable elements has a corresponding unique set of two or more switching resistances and two or more switching currents characteristics, such that combinations of the two or more programmable elements configured in the respective two or more switching resistance correspond to multi-bit binary states controllable by passing switching currents through the common access transistor. Each one of the two or more programmable elements includes one or more hybrid giant spin Hall effect (GSHE)-spin transfer torque (STT) magnetoresistive random access memory (MRAM) cell, with two or more hybrid GSHE-STT MRAM cells coupled in parallel.

### CLAIM OF PRIORITY UNDER 35 U.S.C. §119

The present Application for Patent claims the benefit of Provisional Patent Application No. 61/932,768 entitled “MULTI-LEVEL CELL DESIGNS FOR HIGH DENSITY LOW POWER GSHE-STT MRAM” filed Jan. 28, 2014, pending, and assigned to the assignee hereof and hereby expressly incorporated herein by reference in its entirety.

### FIELD OF DISCLOSURE

Disclosed aspects are directed to multi-level cell designs based on memory elements formed from high density low power hybrid giant spin Hall effect (GSHE)-spin transfer torque (STT) magnetoresistive random access memory (MRAM) structures. In some aspects, two or more memory elements with unique switching resistances and corresponding switching current characteristics can be controlled by a common access transistor, in order to provide high density solutions.

### BACKGROUND

Mobile computing demands high density and high performance memory systems, and specifically, solid state storage devices.

Flash memory is known for its application in mass non-volatile storage systems. However, while Flash memory offers high density, Flash memory tends to be slow, which can cause large programming delays of the order 10 us-1 ms, thus rendering Flash memory undesirable for many high performance applications.

Dynamic random access memory (DRAM) is another example of a popular memory technology used for mass data storage, for example, in main memory structures. DRAM offers characteristics of medium density and medium speed, with programming delays of ˜10 ns. Thus, DRAM technology is also not optimally suited for high density and high performance.

Static random access memory (SRAM) is yet another popular memory technology, commonly used as scratch and in cache memory applications. SRAM technology is fast and may offer programming delays of ˜1 ns, but requires large area for each memory cell, which leads to low density. Accordingly, SRAM technology also fails to satisfy the demands for high density and high performance.

Magnetoresistive random access memory (MRAM) is a non-volatile memory technology that has response (read/write) times comparable to volatile memory. Specifically, spin transfer torque MRAM (STT-MRAM) offers state of the art solutions where an STT-MRAM bit cell uses electrons that become spin-polarized as the electrons pass through a thin film (spin filter). STT-MRAM promises high performance, but density of STT-MRAM is much lower than comparable Flash and DRAM solutions.

Hybrid giant spin Hall effect (GSHE)-spin transfer torque (STT) magnetoresistive random access memory (MRAM) has been disclosed in U.S. patent application Ser. No. 14/451,510, filed on Aug. 5, 2014, entitled, “High Density Low Power GSHE-STT MRAM,” (hereinafter, “the '510 reference”), incorporated herein by reference. As disclosed therein, the hybrid GSHE-STT MRAM element includes a GSHE strip formed between a first terminal (A) and a second terminal (B), and a magnetic tunnel junction (MTJ), with a free layer of the MTJ interfacing the GSHE strip, and a top electrode of the MTJ coupled to a third terminal (C). A magnetization of an easy axis of the free layer of the MTJ is substantially perpendicular to the magnetization direction created by electrons traversing the SHE/GSHE strip between the first terminal and the second terminal, such that the free layer of the MTJ is configured to switch based on a first charge current injected from/to the first terminal to/from the second terminal and a second charge current injected or extracted (i.e., positive/negative current directions) through the third terminal into or out of the MTJ through the top electrode.

Such hybrid GSHE-STT MRAM solutions provide high density and high performance solutions which are superior to the above described known technologies, such as, Flash, DRAM, SRAM, and also, STT-MRAM. However, while these GSHE-STT MRAM solutions offer desirable high density and high performance, limitations on density are imposed by ancillary circuit elements which are used to connect bit cells formed by GSHE-STT MRAM elements to memory arrays. For example, access transistors that are used to connect the GSHE-STT MRAM elements to memory array control lines such as, word lines, and bit lines are based on conventional silicon technology. These access transistors may only be placed or formed on a single silicon layer whereas GSHE-STTT MRAM elements can be formed across multiple layers above the single silicon layer. The access transistors may be larger than the GSHE-STT MRAM elements. Accordingly, the density of memory arrays formed by GSHE-STT MRAM technology is dependent on the footprint of these access transistors. The larger footprint of the access transistors leads to a lower density.

### SUMMARY

Exemplary aspects include systems and methods directed to multi-level cell (MLC) comprising: two or more (n) programmable elements coupled to a common access transistor, wherein each one (e.g., [i]) of the two or more programmable elements has a corresponding unique pair of two or more switching resistances (e.g., RP[i] and RAP[i]) and two or more switching currents (e.g., Ic[i]) characteristics, such that combinations of the two or more programmable elements configured in the respective two or more switching resistance correspond to multi-bit binary states controllable by passing switching currents through the common access transistor, and wherein, each one of the two or more programmable elements comprises one or more hybrid giant spin Hall effect (GSHE)-spin transfer torque (STT) magnetoresistive random access memory (MRAM) cell, the GSHE-STT MRAM cells coupled in parallel.

For example, an exemplary aspect is related to a multi-level cell (MLC) comprising: one or more programmable elements coupled to a common access transistor, wherein each one of the one or more programmable elements has a unique pair of switching resistances corresponding to two binary states respectively. The switching resistances are provided by hybrid giant spin Hall effect (GSHE)-spin transfer torque (STT) magnetoresistive random access memory (MRAM) elements.

Another exemplary aspect is related to a method of forming a multi-level cell (MLC), the method comprising: forming one or more programmable elements with a unique pair of switching resistances corresponding to two binary states respectively, wherein, the switching resistances are provided by hybrid giant spin Hall effect (GSHE)-spin transfer torque (STT) magnetoresistive random access memory (MRAM) elements. The one or more programmable elements are coupled to a common access transistor.

Yet another exemplary aspect is related to a multi-level cell (MLC) comprising: means for providing a unique pair of switching resistances corresponding to two binary states respectively to each of one or more programmable elements, wherein, the switching resistances are based on switching resistances of hybrid giant spin Hall effect (GSHE)-spin transfer torque (STT) magnetoresistive random access memory (MRAM) elements, and a common means for accessing the one or more programmable elements.

### BRIEF DESCRIPTION OF THE DRAWINGS

The accompanying drawings are presented to aid in the description of aspects of the invention and are provided solely for illustration of the aspects and not limitation thereof.

FIG. 1A illustrates a side view of a memory cell 100 comprising hybrid GSHE-STT MRAM bit cells described in the '510 reference.

FIG. 1B illustrates a top view of memory cell 100 depicted in FIG. 1A, with an in-plane MTJ.

FIG. 1C illustrates a top view for a memory cell 100 comprising a perpendicular magnetic anisotropy (PMA) MTJ.

FIG. 1D illustrates a device representation or symbol of memory cell 100.

FIG. 2 illustrates a single-level cell (SLC) GSHE-STT MRAM bit cells as described in the '510 reference.

FIG. 3 illustrates multi-level cell (MLC) GSHE-STT MRAM with two GSHE-STT MRAM elements in a bit cell, according to exemplary aspects.

FIG. 4 illustrates multi-level cell (MLC) GSHE-STT MRAM with n-level heterogeneous GSHE-STT MRAM cells or programmable elements, according to exemplary aspects

FIG. 5 illustrates transitions between programming states for a 3-bit MLC according to exemplary aspects.

FIGS. 6A-D include illustrations related to stacked structures for forming parallel connections within programmable cells of an exemplary MLC.

FIGS. 7A-B include illustrations related to stacked structures for forming series connections within programmable cells of an exemplary MLC according to exemplary aspects.

FIG. 8 illustrates a flow-chart pertaining to a method of forming an MLC according to exemplary aspects.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Exemplary aspects include high density memory structures comprising hybrid GSHE-STT MRAM elements such as the hybrid GSHE-STT MRAM elements described in the '510 reference. Since the size of the access transistor coupling GSHE-STT MRAM bit cells to a memory array has been recognized in the foregoing sections as a limiting factor in increasing density of GSHE-STT MRAM based memory, aspects include solutions for sharing an access transistor across two or more GSHE-STT MRAM bit cells. In this manner, the density is improved. Exemplary multi-level cells with two or more hybrid GSHE-STT MRAM elements coupled in parallel provide unique sets of two or more switching resistances and corresponding switching current characteristics, where the shared or common access transistor can be used to program these multi-level cells into multiple binary states.

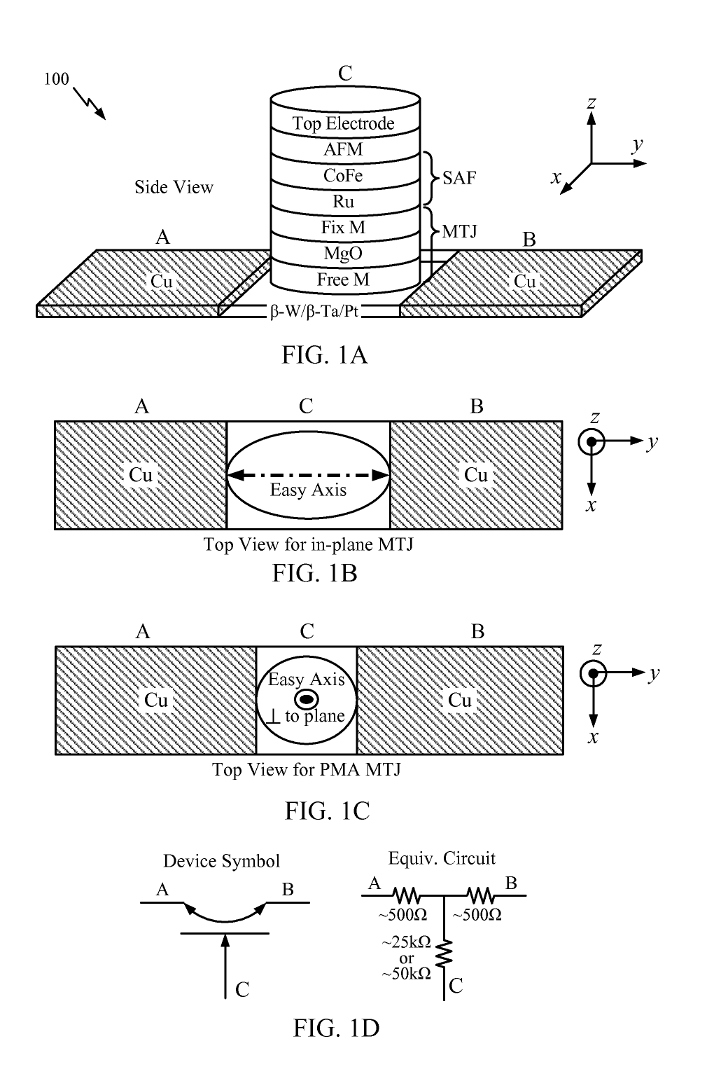

Initially, the structure of the GSHE-STT MRAM element, as described in the '510 reference, will be explained. With reference to FIG. 1A, a side view of memory element 100 is provided. A GSHE strip is formed between terminals A and B, which may be formed from metals such as copper. A magnetic tunneling junction (MTJ) structure is formed on the GSHE strip, with a free layer of the MTJ interfacing the GSHE strip. Write current I_{w} is passed through the GSHE strip in either direction between A and B. A magnetic polarity is induced in a substantially perpendicular direction to the write current on a surface of the GSHE strip due to spin Hall effect, magnified by adjusting dimensions of the GSHE strip. Based on this induced polarization, the free layer of the MTJ can be switched. Additionally, in memory cell 100, optional layers Ru, and CoFe, and an anti-ferromagnetic layer (AFM), along with a top electrode are also depicted. The MTJ is read based on sensing the read current I_{read} passed through the terminal C coupled to the top electrode.

Referring to the top view of memory element 100 depicted in FIG. 1B, it is seen that the MTJ in memory cell 100 is oriented such that an easy axis of the MTJ is substantially perpendicular to the magnetization induced by the GSHE strip. The perpendicular directions of the easy axis and the magnetization direction created by electrons traversing the GSHE strip result in easy switching of the free layer of the MTJ based on the well-known principles derived from the Stoner-Wohlfarth astroid or curve. Accordingly, from FIGS. 1A-B, with the easy axis (y-axis) perpendicular to the GSHE magnetization or spin orientation (x-axis), memory element 100 is designed to enable switching the free layer of the MTJ when there is a much lower threshold of current flow between A and B (in either direction), since the switching of the MTJ is based on a combination of spin-torque transfer (STT) switching in the perpendicular direction (z-axis in FIG. 1B, for example), as well as, due to the GSHE based magnetization. Accordingly, the combination is referred to as a hybrid GSHE-STT MRAM. It will be recognized that for an MTJ, the magnetization of the fixed layer is fixed and when the direction of the free layer is aligned to the fixed layer, the low MTJ resistance state exists and when the direction of the free layer and the fixed layer are mis-aligned, then the high MTJ resistance exists. When current from/to first terminal A to/from second terminal B is no less than a threshold (˜20 uA), the MTJ switches to state “0” (low MTJ resistance) if there is sufficient current flow out of third terminal C (coupled to the top electrode of the MTJ, for example). Similarly, the MTJ switches to state “1” (high MTJ resistance) if there is sufficient current flow into third terminal C. When current from/to first terminal A to/from second terminal B is less than the threshold (˜20 uA) and current flows into or out of third terminal C is small as well, the previous state (either “0” or “1”) of MTJ is maintained.

Thus, in general, an aspect of this disclosure can include a hybrid GSHE-STT MRAM element comprising a GSHE strip formed between a first terminal A and a second terminal B, and a MTJ, with a free layer of the MTJ interfacing the GSHE strip, and a top electrode of the MTJ coupled to a third terminal C. The orientation of the easy axis of the free layer is perpendicular to the magnetization created by electrons traversing the GSHE strip between the first terminal and the second terminal, such that the free layer of the MTJ is configured to switch based on a first charge current injected from/to the first terminal to/from the second terminal and a second charge current injected or extracted through the third terminal into or out of the MTJ through the top electrode.

With reference to FIG. 1D, a device representation or symbol of memory element 100 is shown, with the double arrows between first and second terminals “A” and “B” indicating the dual direction in which current flow may affect switching of the free layer of the MTJ coupled to third terminal “C.” From the equivalent circuit representation, it is seen that the resistance between the terminals A, and B of the 3-terminal memory element 100 is extremely low, (in the order of a few hundred ohms), and therefore, the MTJ can be programmed with ease.

FIG. 1B depicts the top view for exemplary memory element 100 for an in-plane MTJ. With reference to FIG. 1C, the top view for an exemplary memory element 100 comprising a perpendicular magnetic anisotropy (PMA) MTJ, where the easy axis of the PMA MTJ is perpendicular to the plane (i.e., z-axis or z direction). Once again, the easy axis is perpendicular to the GSHE magnetization or spin orientation along the x-axis, and the operation of the aspect of memory element 100 comprising the PMA MTJ stacked on the GSHE strip according to FIG. 1C is similar to that explained above with reference to the in-plane MTJ of FIG. 1B.

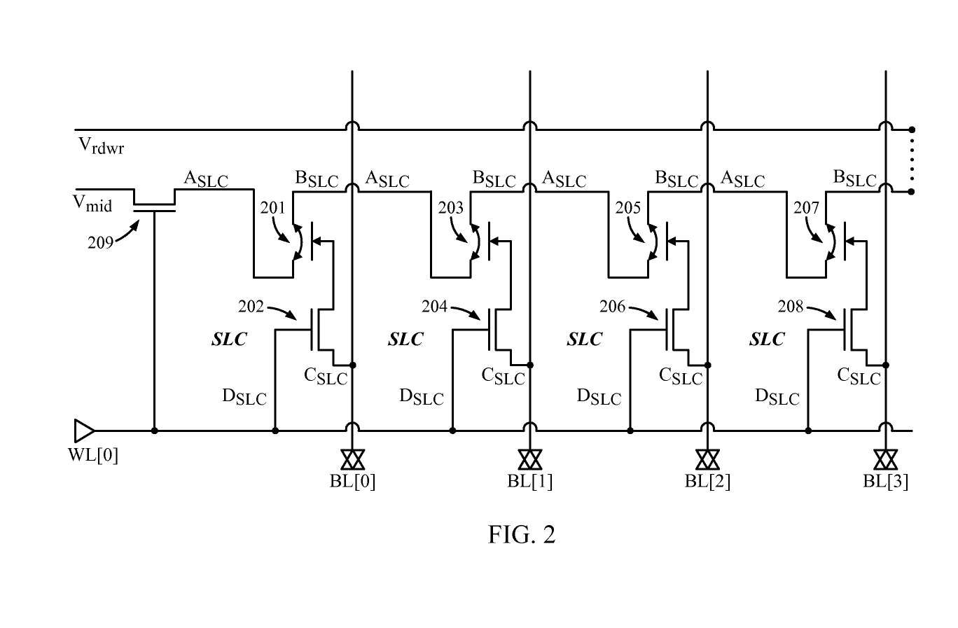

Exemplary aspects of this disclosure are directed to memory arrays comprising GSHE-STT MTJs or hybrid GSHE-STT MRAM technology. FIG. 2 depicts an arrangement of the hybrid GSHE MRAM elements, for example, as described in the '510 reference, where a row of a memory array comprising hybrid GSHE-STT MRAM elements 201, 203, 205, and 207 is shown. Each of these GHSE-STT MRAM elements is coupled to a corresponding access transistor 202, 204, 206, and 208 respectively, with one access transistor per bit cell (as described herein, a bit cell refers to a structure comprising one or more access transistors coupled to one or more memory elements). This arrangement is referred to herein as a single-level cell (SLC). Within the illustrated row, the GSHE-STT MRAM cells 201, 203, 205, and 207 are shown to have the above-described three terminals A, B, and C, which are labeled as A_{SLC}, B_{SLC}, and C_{SLC}. The GSHE-STT MRAM cells 201, 203, 205, and 207 are connected in series and to a shared pass transistor 209 to connect to a midpoint voltage (Vmid). The other end of the series connection is coupled to a read-write voltage (Vrdwr) used to control the voltage values used for read or write operations. Each of GSHE-STT MRAM cells 201, 203, 205, and 207 is connected to a drain of a corresponding access transistors 202, 204, 206, and 208, where the gate of the access transistor is connected a fourth terminal D_{SLC}, which couples the corresponding SLC to the word lines of each row in a memory array, (e.g., WL[0]). The source/drain terminals of the access transistors 202, 204, 206, and 208 are connected to bit lines BL [0, 1, 2, . . . ] respectively. As previously noted, the sizes of the access transistors 202, 204, 206, and 208 are significantly larger than the sizes of corresponding GSHE-STT MRAM cells 201, 203, 205, and 207.

Accordingly, exemplary aspects will now be described with relation to multi-level cells, which can provide higher density in memory arrays, in comparison to single-level cells.

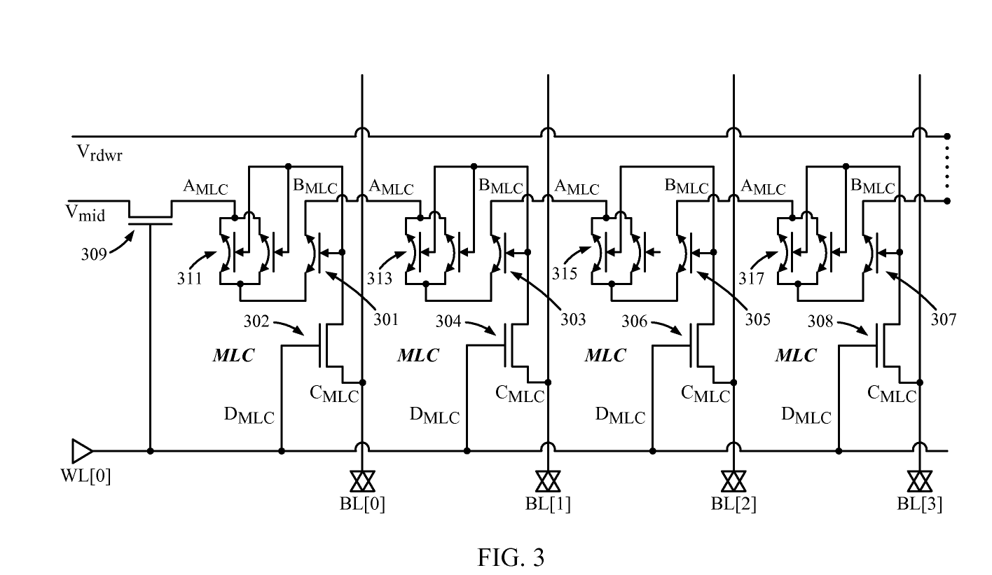

With reference to FIG. 3, aspects of a memory array comprising exemplary multi-level cell (MLC) GSHE-STT MRAM memory cells are illustrated. Similar to FIG. 2, in FIG. 3, within the depicted row, the GSHE-STT MRAM cells 301, 303, 305, and 307 are connected to corresponding access transistors 302, 304, 306, and 308, where the gate of the access transistor is connected to the word lines corresponding to the row, WL[0], and the source of the access transistor is connected to bit lines BL[0, 1, 2, . . . ]. However, deviating from the SLC depiction of FIG. 2, FIG. 3 also includes additional GSHE-STT MRAM elements within each memory cell. The additional GSHE-STT MRAM elements are composite GSHE-STT MRAM elements and denoted 311, 313, 315, and 317, with each one of the composite GSHE-STT MRAM elements 311, 313, 315, and 317 comprising two GSHE-STT MRAM elements coupled in parallel through their respective first terminals (A_{MLC}) and second terminals (B_{MLC}). In turn, each of the composite GSHE-STT MRAM elements 311, 313, 315, and 317 comprising two GSHE-STT MRAM elements each are also coupled in parallel to corresponding GSHE-STT MRAM elements 301, 303, 305, and 307. The access transistors 302, 304, 306, and 308 form common access means for the GSHE-STT MRAM elements and are thus coupled to the GSHE-STT MRAM elements 301, 303, 305, and 307, as well as, the composite GSHE-STT MRAM elements 311, 313, 315, and 317 comprising two GSHE-STT MRAM elements, through the third or read terminals (C_{MLC}) of each of these GSHE-STT MRAM cells, such that a shared or common access transistor or common means for accessing is coupled to three GSHE-STT MRAM cells within each bit cell of the row. The gate of the common access transistor acts as an access enable terminal or fourth terminal D_{MLC} of the multi-level cells, where the access enable terminal (D_{MLC}) is coupled to the word line WL[0]. The particular GSHE-STT MRAM cells may thus be enabled through access enable terminal (D_{MLC}) when the corresponding word line WL[0] is selected or active high. Similar to the SLCs of FIG. 2, the MLCs of FIG. 3 are also connected to midpoint voltage Vmid and read-write voltage Vrdwr, as shown.

Due to the parallel connection of the two GSHE-STT MRAM elements within composite GSHE-STT MRAM elements 311, 313, 315, and 317, the resistance of the composite GSHE-STT MRAM elements 311, 313, 315, and 317 is different from the resistance of corresponding GSHE-STT MRAM elements 301, 303, 305, and 307 within the bit cells. In other words, each bit cell now comprises two different resistance elements coupled to a common access transistor. For example, focusing on a first MLC bit cell coupled to pass transistor 309, the first bit cell comprises GSHE-STT MRAM element 301 of a first resistance in the low resistance state or logic “0” state of its MTJ (e.g., R_{P}[1]) and a second resistance in the high resistance or logic “1” state of its MTJ (R_{AP}[1]); and similarly, composite GSHE-STT MRAM element 311 has a third resistance corresponding to its logic “0” state (e.g., R_{P}[2]) and a fourth resistance corresponding to its logic “1” state (e.g., R_{AP}[2]). The current required to switch each of these four resistances is different, and therefore, the first MLC bit cell can be programmed to four binary states corresponding to “00” (R_{P}[1], R_{P}[2]), “01” (R_{P}[1], R_{AP}[2]), “10” (R_{AP}[1], R_{P}[2]), and “11” (R_{AP}[1], R_{AP}[2]).

In more detail, transition between the four binary states for the first MLC bit cell can be controlled through the common access transistor 302. For example, starting from state “00” (R_{P}[1], R_{P}[2]), which may be assumed to be the initialized state, a low switching current, which is sufficient to switch composite GSHE-STT MRAM element 311, but not GSHE-STT MRAM element 301, can be applied through access transistor 302 in a first direction. This will leads to state “10” (R_{AP}[1], R_{P}[2]) in the first MLC bit cell. If a higher current is injected which will switch both 311 and 301, then state transition to “11” (R_{AP}[1], R_{AP}[2]) can be achieved. From thereon, if current is applied in a reverse direction, sufficient to flip GSHE-STT MRAM element 301 but not GSHE-STT MRAM element 311, then the state can transition to “10” (R_{AP}[1], R_{P}[2]). In this manner, all four binary states can be programmed in the first MLC bit cell. Similarly, all cells within the row can be programmed.

The above notion of programming MLC bit cells can be extended to any number of levels. For example, a MLC bit cell can have n elements with unique resistance values for R_{P} and R_{AP}, with each of the n elements flipping between these two resistance states based on correspondingly unique switching currents I_{c}. Each of these n unique elements within a MLC bit cell can be a single GSHE-STT MRAM or a composite GSHE-STT MRAM element having a unique number of two or more GSHE-STT MRAM elements coupled in parallel. A GSHE-STT MRAM element and one or more unique composite elements comprising a unique number of two or more GSHE-STT MRAM elements coupled in parallel can be coupled to an access transistor.

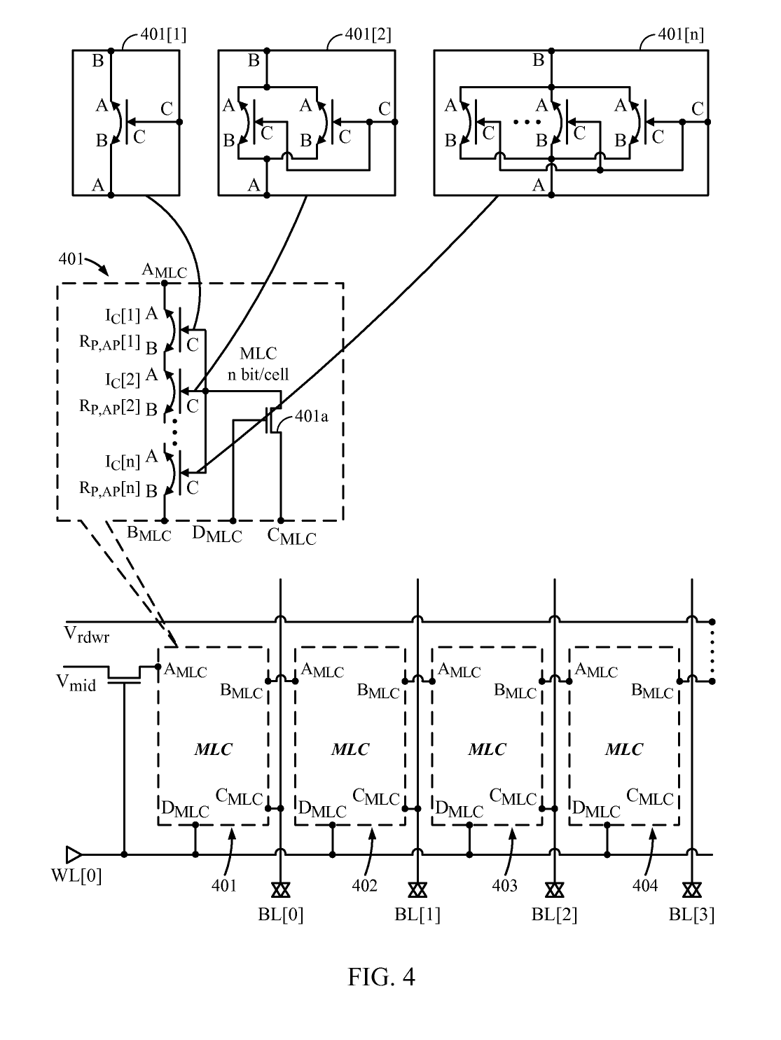

With reference now to FIG. 4, a row of an exemplary memory array comprising MLC bit cells 401-403 is illustrated. The structure of these bit cells in FIG. 4 is similar to the above-described features in FIG. 3, but extended to a generic n number of programmable elements controlled by a single shared or common access transistor within each bit cell. In more detail, MLC bit cell 401 is considered. As shown, MLC bit cell 401 includes access transistor 401A coupled to n programmable elements labeled 401[1], 401[2] . . . 401[n]. At least one of these n programmable elements comprises two or more GSHE-STT MRAM elements coupled in parallel. With these n programmable elements, 2ⁿ logic states are possible. Programmable elements 401[1] and 401[2] may correspond to GSHE-STT MRAM element 301 and composite GSHE-STT MRAM element 311 of FIG. 3, whose operation was discussed in detail above. Composite programmable element 401[n] includes n GSHE-STT MRAM elements connected in parallel, with corresponding resistance values R_{AP}[n] and R_{P}[n]. As previously, the programming terminals A_{MLC} of each of the n GSHE-STT MRAM cells are connected, and the programming terminals B_{MLC} of each of the n GSHE-STT MRAM cells are connected, as shown. The drain of the access transistor 401A is connected to each of the read terminals (C_{MLC}) of the n programmable elements. In some aspects, the parallel connections of n programmable elements may be stacked as shown for MLC bit cell 401. The 2ⁿ logic states can be traversed in similar fashion as was explained above for 2²=4 programmable states with reference to FIG. 3 where each MLC bit cell was shown to comprise n=2 programmable elements. Skilled persons will recognize how to program a general number of 2ⁿ states based on this disclosure.

With regard to reading or sensing the binary values or detecting the resistance states of the MLC bit cells 401-404, a same voltage, e.g., Vdd/2 may be applied as V_{AMLC} and V_{BMLC} to the MLC write terminals A_{MLC} and B_{MLC} shown in FIG. 4. A different voltage V_{CMLC} may be applied on the read terminal, C_{MLC} where the voltage V_{CMLC} may be with small delta (e.g., ˜0.1V), above V_{AMLC} and V_{BMLC}. The resistance between C_{MLC} and a merged voltage at the terminals A_{MLC} and B_{MLC} may be measured in order to sense the resistance state stored within the MLC bit cell lying between the terminals A_{MLC}, B_{MLC} and C_{MLC}.

Once again, with regard to programming a MLC bit cell, a corresponding write current, I_{write}, may be applied across MLC write terminals A_{MLC} and B_{MLC}. A different voltage V_{CMLC} may be applied on terminal C_{MLC} with small delta (e.g., ˜0.1V), above V_{AMLC} and V_{BMLC} for a positive value “+” of I_{write} (i.e., current traversing in a first direction). The voltage V_{CMLC} may be applied on terminal C_{MLC} with small delta (e.g., ˜0.1V), below V_{AMLC} and V_{BMLC} for a negative value “−” of I_{write} (i.e., current traversing in a reverse or second direction) for a predetermined duration. An exemplary sequence of positive or negative I_{write} currents are representatively illustrated for n=3, or for a 3 bit MLC bit cell or in other words, an MLC bit cell with three programmable elements or bits “1,” “2,” and “3.”

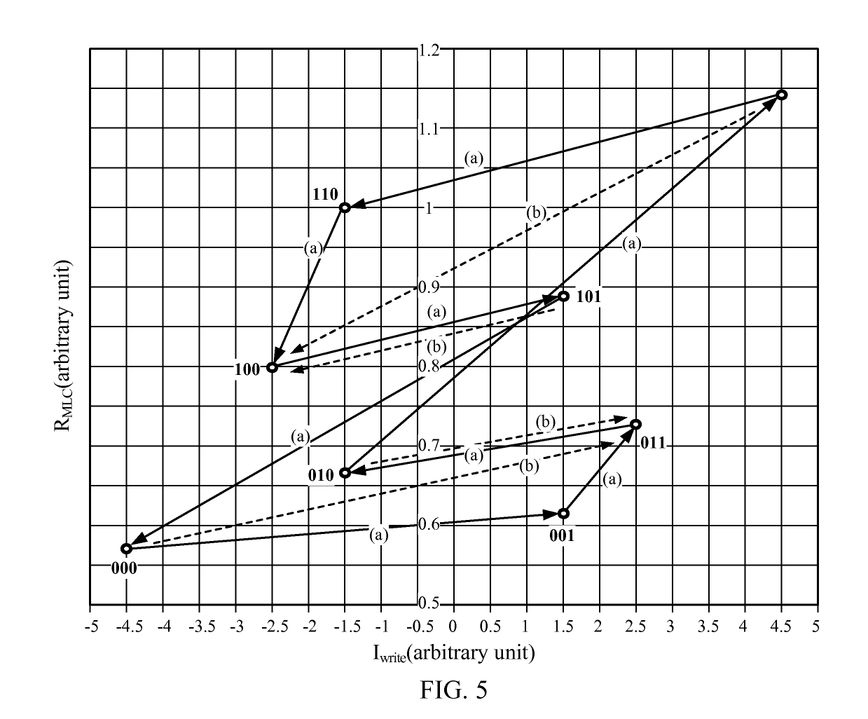

With reference to FIG. 5, programming states and programming paths for traversing through the programming states are illustrated for a 3-bit MLC (i.e., a MLC GSHE-STT MRAM bit cell comprising 3 programmable elements coupled to a common access transistor). The 3-bit MLC may be part of a row of a memory array, where the row may comprise one or more additional similar 3-bit MLCs. With 3 bits, 2³=8 binary states are possible. These 8 binary states will be referred to, herein, as “MLC states” or “MLC logic states”. The 8 MLC states correspond to the various combinations of Rₚ[1, 2, 3] and R_{AP}[1, 2, 3] states, and these 8 MLC states can be reached by traversing from one state to another by the passage of positive or negative I_{write} (i.e., write currents in either direction). Accordingly, if the write current values of I_{write} were considered on a normalized scale, then, I_{c}[1] represents the write current (also known as “critical current”) that is required to flip resistance state Rₚ[1] to R_{AP}[1] for programmable element “1”. Similarly, I_{c}[2], and I_{c}[3], relate to the write currents for flipping R_{P}[2] to R_{AP}[2] and R_{P}[3] to R_{AP}[3] for programmable elements “2” and “3” respectively. The reverse write current or I_{write} in the second direction is required for flipping the resistance states in the opposite direction, as indicated by negative “−” current values in the figure.

Specifically, in FIG. 5, the transition paths denoted with numerical identifier “(a)” illustrate the MLC state transitions, with the following write current value and corresponding state transitions. For bit “1” or programmable element “1,” write current I_{c}[1]=1, which corresponds to R_{P}[1]=4 and R_{AP[}1]=2R_{P}[1]=8. For bit “2” or programmable element “2” I_{c}[2]=2, which corresponds to R_{P}[2]=2 and R_{AP}[2]=2R_{P}[2]=4. For bit “3” or programmable element “3,” I_{c}[3]=4, which corresponds to resistance R_{P}[3]=1 and R_{AP}[3]=2R_{P}[3]=2;

With regard to state transitions based on the above write current values for bits “1,” “2,” and “3,” MLC state “000” can always be reached with I_{write}<−4, regardless of the initial state of the MLC bit cell. This is because a low enough write current flips all 3 programmable elements to their logic “0” states. MLC state “111” can always be reached with I_{write}>+4, regardless of the initial state of the MLC bit cell, because a high enough current flips all 3 programmable elements to their logic “1” states. Thus, the binary minimum value for 3 bits, i.e., “000” can be reached with passing a write current which is low enough to flip all three programmable elements to their logic “0” states, wherein this write current may be referred to as a minimum switching current. Similarly, the binary maximum value for 3 bits, i.e., “111” can be reached with passing a write current which is low enough to flip all three programmable elements to their logic “1” states, wherein this write current may also be referred to as a maximum switching current.

In addition to the state transition paths shown with the numerical identifier “(a)” and the above-mentioned transition paths to states “000” and “111,” FIG. 5 also illustrates transition paths shown with the numerical identifier “(b).” State transitions based on these paths (b) along with corresponding write current I_{write} values are as follows. For a write current of negative value or −I_{write}=1.5 the state transitions from “010” to “011” and from “101” to “100.” For a write current of negative value or −I_{write}=2.5 the stat transitions from “000” to “011” and from “111” to “100.”

Accordingly, an efficient manner of programming an n bit MLC bit cell includes reading the MLC bit cell in order to detect the current or initial state of the MLC bit cell, and then choosing the optimal path(s) among the various illustrated transition paths (a), as well as, from the additional paths (b). In this manner, programming delay and power can be optimized. As previously noted, the common access transistor for programming all n bits or programming elements within a single MLC bit cell contributes to significant savings in terms of area, and thus, can achieve high density memory configurations using the GSHE-STT MRAM technology.

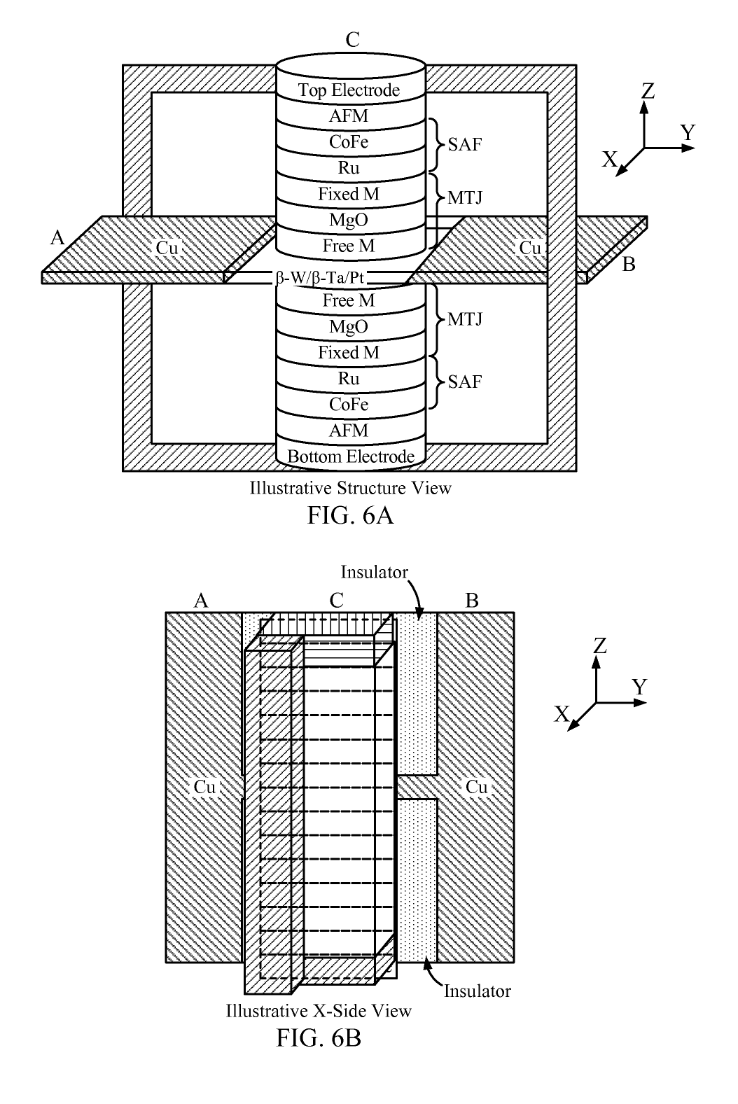

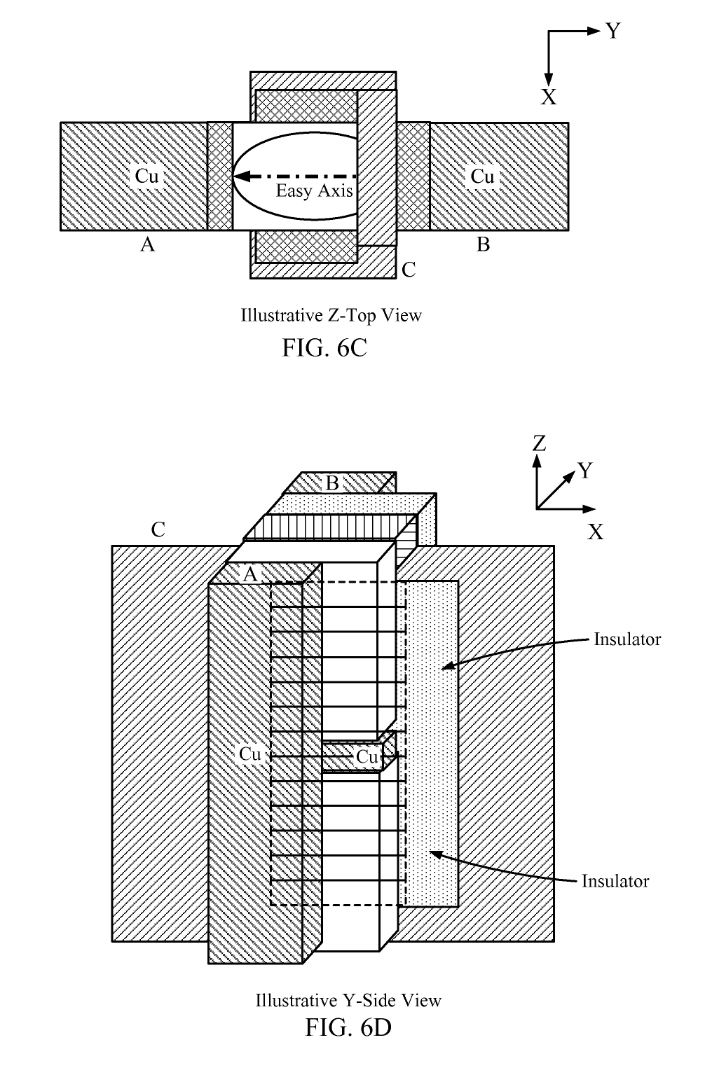

With reference now to FIGS. 6A-D, stacked structures for forming the above-described MLC bit cells are shown. More specifically, FIG. 6A illustrates two MTJs stacked on either side of the GSHE strip, such as the one shown in FIG. 1A. The top MTJ is coupled to a top electrode and the bottom MTJ is coupled to a bottom electrode. The terminals A and B of the top and bottom electrode are already connected in the required order to form the 2 cell programmable GSHE-STT MRAM element 311 of FIG. 3 for example. It is possible to further extend this notion by also coupling MTJ elements to either sides of the GSHE strip (i.e., the exposed sides on the x-y plane) in order to couple more MTJ elements to form different resistance states. The GSHE strip need not be limited to a cuboidal shape with 6 sides, but may be any polygonal shape coupling the two terminals A and B, thus, theoretically allowing any number of n MTJs to be formed, for creating a GSHE-STT MRAM element of resistance states R_{P}[n] and R_{AP}[n]. FIG. 6B illustrates a side view of the structure of FIG. 6A in the x-direction; FIG. 6C illustrates a top view of the structure of FIG. 6A in the z-direction; and FIG. 6D illustrates a side view of the structure of FIG. 6A in the y-direction.

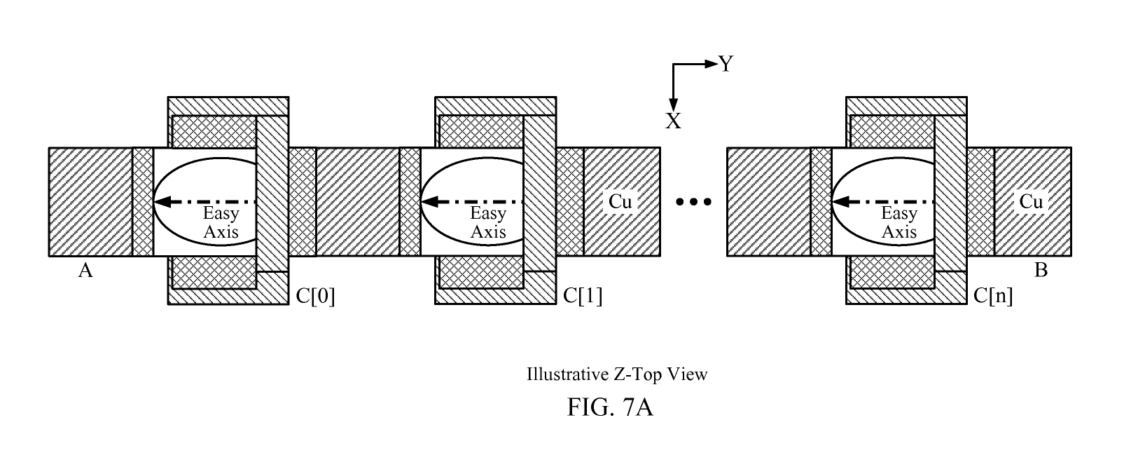

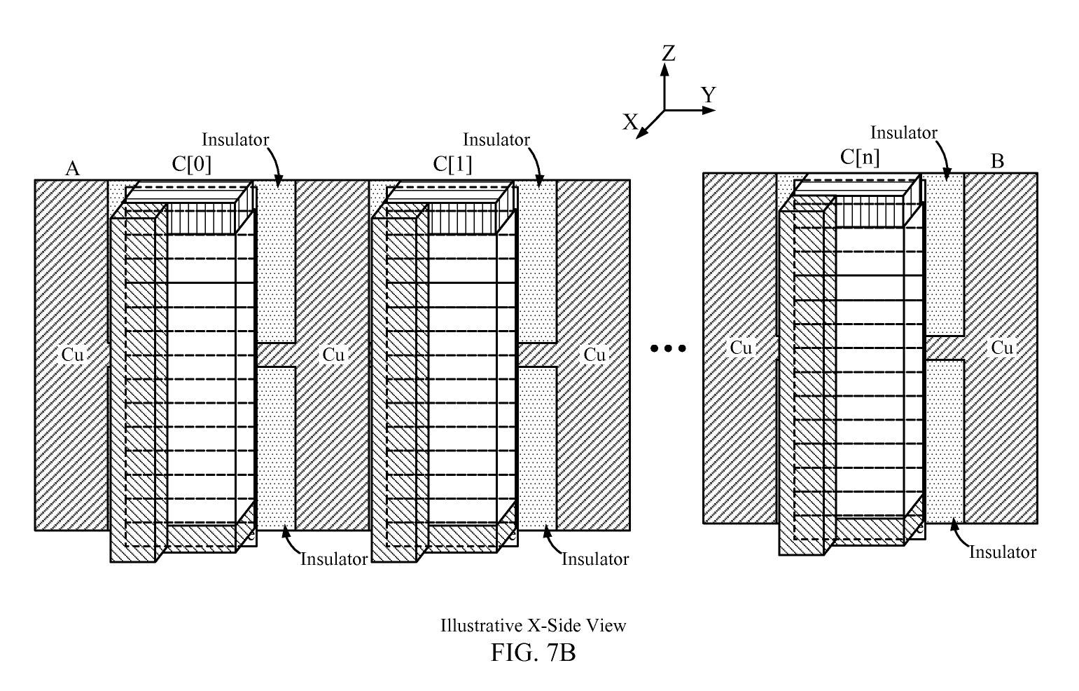

Referring to FIG. 7A, a top view from a z-direction of yet another stacking arrangement has been illustrated wherein the second terminal (B) of a first MLC cell ([1]) is shared with a first terminal (A) of a second MLC cell ([2]) of n MLCs, such that the same terminal is used for both the second terminal (B) of the first MLC cell [1] and the first terminal (A) of the second MLC cell [2]. In this manner, MLC cells [1] and [2] can be connected in series. As illustrated, this notion can be extended to n MLC cells, with the last MLC cell being MLC cell [n]. The third terminal C [1, 2 . . . n] of the n MLC cells is available for read operations according to previously described aspects. FIG. 7B illustrates a corresponding side view of FIG. 7A, in the x-direction.

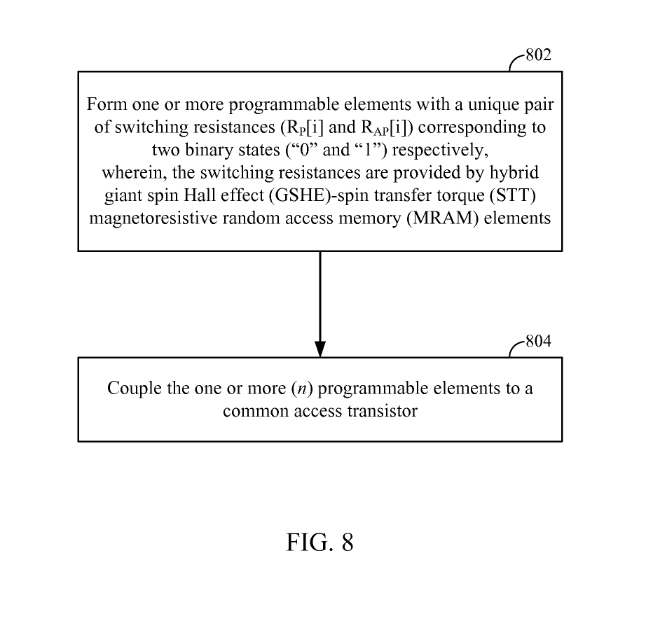

Accordingly, a description of exemplary aspects related to MLC cells formed from memory elements comprising hybrid GSHE-STT MRAM memory cells, the MLC cells connected to a shared access transistor for improving density, have been presented. It will be appreciated that aspects include various methods for performing the processes, functions and/or algorithms disclosed herein. For example, as illustrated in FIG. 8, an aspect can include a method of forming a multi-level cell (e.g., MLC 401), the method comprising: forming one or more programmable elements with a unique pair of switching resistances (R_{P}[i] and R_{AP}[i]) corresponding to two binary states (“0” and “1”) respectively, wherein, the switching resistances are provided by hybrid giant spin Hall effect (GSHE)-spin transfer torque (STT) magnetoresistive random access memory (MRAM) elements—Block 802; and coupling the one or more (n) programmable elements to a common access transistor (e.g., access transistor 401A)—Block 804.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the aspects disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an exemplary aspect can include a computer readable media embodying a method for forming exemplary hybrid GSHE-STT MRAM cells and related circuit topologies and memory arrays. Accordingly, the invention is not limited to illustrated examples and any means for performing the functionality described herein are included in aspects of the invention.

While the foregoing disclosure shows illustrative aspects of the invention, it should be noted that various changes and modifications could be made herein without departing from the scope of the invention as defined by the appended claims. The functions, steps and/or actions of the method claims in accordance with the aspects of the invention described herein need not be performed in any particular order. Furthermore, although elements of the invention may be described or claimed in the singular, the plural is contemplated unless limitation to the singular is explicitly stated.

What is claimed is:

1. A multi-level cell (MLC) comprising:
one or more programmable elements coupled to a common access transistor,
wherein each one of the one or more programmable elements has a unique pair of switching resistances corresponding to two binary states respectively,
wherein, the switching resistances are provided by hybrid giant spin Hall effect (GSHE)-spin transfer torque (STT) magnetoresistive random access memory (MRAM) elements.

2. The MLC of claim 1, wherein at least one programmable element comprises two or more hybrid GSHE-STT MRAM elements coupled in parallel.

3. The MLC of claim 1, wherein and each of the one or more programmable elements is configured to switch between the two binary states based on a corresponding unique switching current passed through the common access transistor.

4. The MLC of claim 1, wherein a first write terminal of the MLC and a second write terminal of the MLC are coupled by a series connection of the one or more programmable elements.

5. The MLC of claim 1, wherein a third terminal of the MLC is coupled to drain/source terminal of the access transistor, and the corresponding source/drain terminal of the access transistor is coupled to read terminals of each of the one of the two or more programmable elements.

6. The MLC of claim 1, further comprising an access enable terminal to enable the MLC, the access enable terminal coupled to a gate terminal of the access transistor.

7. The MLC of claim 1, wherein the one or more programmable elements are programmed based on a read operation to determine an initial state of the one or more programmable elements, followed by a write operation comprising a corresponding switching current to appropriately switch binary states of the one or more programmable elements in order to transition to a state corresponding to the desired write value.

8. The MLC of claim 1, wherein the one or more programmable elements are programmed based on initializing the states of each of the programmable elements to a binary maximum or a binary minimum by passing a corresponding maximum or minimum switching current, prior to performing a write operation.

9. The MLC of claim 1 wherein magnetic tunnel junctions (MTJs) of selected ones of the one or more programmable elements are connected in parallel to form composite MTJs, such that first terminals of the selected programmable elements are formed by the first write terminals of the MTJs coupled together, and second terminals of the selected programmable elements are formed by the second write terminals of the MTJs coupled together and third terminals of the selected programmable elements are formed by the third terminals of the MTJs coupled together.

10. The MLC of claim 9, wherein the parallel connection of the MTJs comprise stacked structures sharing the first terminals and the second terminals and a common GSHE strip.

11. A method of forming a multi-level cell (MLC), the method comprising:
forming one or more programmable elements with a unique pair of switching resistances corresponding to two binary states respectively,
wherein, the switching resistances are provided by hybrid giant spin Hall effect (GSHE)-spin transfer torque (STT) magnetoresistive random access memory (MRAM) elements; and
coupling the one or more programmable elements to a common access transistor.

12. The method of claim 11, comprising coupling two or more GSHE-STT MRAM elements in at least one of the one or more programmable elements.

13. The method of claim 12, comprising passing a unique switching current through the common access transistor to cause a corresponding one of the one or more programmable elements to switch between the two binary states.

14. The method of claim 11, comprising coupling a first write terminal of the MLC and a second write terminal of the MLC in a series connection of the one or more programmable elements.

15. The method of claim 11, comprising coupling a third terminal of the MLC is to a drain/source terminal of the access transistor, and coupling the corresponding source/drain terminal of the access transistor to read terminals of each of the one of the two or more programmable elements.

16. The method of claim 11, further comprising coupling an access enable terminal to a gate terminal of the access transistor, the access enable terminal enable terminal to enable the MLC.

17. The method of claim 11, comprising:
programming the one or more programmable elements based on a read operation to determine an initial state of the one or more programmable elements; and
performing a write operation comprising passing a corresponding switching current, to appropriately switch binary states of the one or more programmable elements in order to transition to a state of the programmable elements to the desired write value.

18. The method of claim 11, comprising programming the one or more programmable elements based on initializing the states of each of the programmable elements to a binary maximum or a binary minimum by passing a corresponding maximum or minimum switching current, prior to performing a write operation.

19. The method of claim 11, comprising connecting magnetic tunnel junctions (MTJs) of selected ones of the one or more programmable elements in parallel to form composite MTJs, such that first terminals of the selected programmable elements are formed by the first write terminals of the MTJs coupled together, and second terminals of the selected programmable elements are formed by the second write terminals of the MTJs coupled together and third terminals of the selected programmable elements are formed by the third terminals of the MTJs coupled together.

20. The method of claim 19, comprising forming the parallel connection of the MTJs with stacked structures sharing the first terminals and the second terminals and a common GSHE strip.

21. A multi-level cell (MLC) comprising:
means for providing a unique pair of switching resistances corresponding to two binary states respectively to each of one or more programmable elements,
wherein, the switching resistances are based on switching resistances of hybrid giant spin Hall effect (GSHE)-spin transfer torque (STT) magnetoresistive random access memory (MRAM) elements; and
a common means for accessing the one or more programmable elements.

22. The MLC of claim 21, comprising means for coupling two or more GSHE-STT MRAM elements in at least one of the one or more programmable elements.

23. The MLC of claim 22, comprising means for causing one of the one or more programmable elements to switch between the two binary states based on a unique switching current corresponding to the programmable element.

24. The MLC of claim 21, comprising means for enabling the MLC through the common means for accessing.

25. The MLC of claim 21, comprising means for initializing, prior to a write operation, the one or more programmable elements based on a corresponding maximum or minimum switching current passed through the programmable elements.
